(19) United States
(12) Patent Application Publication
(10) Pub. No.: US 2013/0095598 A1
(43) Pub. Date: Apr. 18, 2013

(54) BACK-SURFACE FIELD STRUCTURES FOR MULTI-JUNCTION III-V PHOTOVOLTAIC DEVICES

(71) Applicants: Stephen W. Bedell, Wappingers Falls, NY (US); Bahman Hekmatshoar-Tabari, Mount Kisco, NY (US); Devendra K. Sadana, Pleasantville, NY (US); Ghavam G. Shahidi, Round Ridge, NY (US); Davood Shahrjerdi, Ossining, NY (US)

(72) Inventors: Stephen W. Bedell, Wappingers Falls, NY (US); Bahman Hekmatshoar-Tabari, Mount Kisco, NY (US); Devendra K. Sadana, Pleasantville, NY (US); Ghavam G. Shahidi, Round Ridge, NY (US); Davood Shahrjerdi, Ossining, NY (US)

(73) Assignee: International Business Machines Corporation, Armonk, NY (US)

(21) Appl. No.: 13/602,122

(22) Filed: Sep. 1, 2012

Related U.S. Application Data
(63) Continuation of application No. 13/274,938, filed on Oct. 17, 2011.

(51) Int. Cl. H01L 31/18

(52) U.S. Cl. 438/72; 257/E31.127

(57) ABSTRACT

A multi-junction III-V photovoltaic device is provided that includes at least one top cell comprised of at least one III-V compound semiconductor material; and a bottom cell in contact with a surface of the at least one top cell. The bottom cell includes a germanium-containing layer in contact with the at least one top cell, at least one intrinsic hydrogenated silicon-containing layer in contact with a surface of the germanium-containing layer, and at least one doped hydrogenated silicon-containing layer in contact with a surface of the at least one intrinsic hydrogenated silicon-containing layer. The intrinsic and doped silicon-containing layers can be amorphous, nano/micro-crystalline, poly-crystalline or single-crystalline.

### CROSS REFERENCE TO RELATED APPLICATION

This application is a continuation of U.S. patent application Ser. No. 13/274,938, filed Oct. 17, 2011 the entire content and disclosure of which is incorporated herein by reference.

### BACKGROUND

The present disclosure relates to a photovoltaic device and a method of forming the same. More particularly, the present disclosure relates to a back-surface field structure for a multi-junction III-V photovoltaic device which enhances the total open-circuit voltage of the photovoltaic device.

A photovoltaic device is a device that converts the energy of incident photons to electromotive force (e.m.f.). Typical photovoltaic devices include solar cells, which are configured to convert the energy in the electromagnetic radiation from the Sun to electric energy. Each photon has an energy given by the formula E=hv, in which the energy E is equal to the product of the Plank constant h and the frequency v of the electromagnetic radiation associated with the photon.

A photon having energy greater than the electron binding energy of a matter can interact with the matter and free an electron from the matter. While the probability of interaction of each photon with each atom is probabilistic, a structure can be built with a sufficient thickness to cause interaction of photons with the structure with high probability. When an electron is knocked off an atom by a photon, the energy of the photon is converted to electrostatic energy and kinetic energy of the electron, the atom, and/or the crystal lattice including the atom. The electron does not need to have sufficient energy to escape the ionized atom. In the case of a material having a band structure, the electron can merely make a transition to a different band in order to absorb the energy from the photon.

The positive charge of the ionized atom can remain localized on the ionized atom, or can be shared in the lattice including the atom. When the positive charge is shared by the entire lattice, thereby becoming a non-localized charge, this charge is described as a hole in a valence band of the lattice including the atom Likewise, the electron can be non-localized and shared by all atoms in the lattice. This situation occurs in a semiconductor material, and is referred to as photogeneration of an electron-hole pair. The formation of electron-hole pairs and the efficiency of photogeneration depend on the band structure of the irradiated material and the energy of the photon. In case the irradiated material is a semiconductor material, photogeneration occurs when the energy of a photon exceeds the band gap energy, i.e., the energy difference between conduction and valence energy band edges of the irradiated material.

The direction of travel of charged particles, i.e., the electrons and holes, in an irradiated material is sufficiently random (known as carrier “diffusion”). Thus, in the absence of an electric field, photogeneration of electron-hole pairs merely results in heating of the irradiated material. However, an electric field can break the spatial direction of the travel of the charged particles to harness the electrons and holes formed by photogeneration.

Multi-junction solar cells including compound semiconductor sub-cells are widely used for power generation in space due to their high efficiency and radiation stability. In addition, there is an extensive research activity to enable a cost-competitive technology for the use of these high-efficiency solar cells in terrestrial applications. The efforts include further increase of the conversion efficiency by introducing new structures and materials, utilizing concentrators, and further reduction of the cost associated with the substrate.

Multi-junction solar cells are mainly fabricated on germanium (Ge) substrates due to the inherently strong infra-red (IR) absorption property of Ge. This coupled with the fact that Ge is lattice matched with some of the III-V materials allow the integration of III-V sub cells on a Ge substrate, where the substrate serves as the bottom cell.

One common approach for further enhancement of the conversion efficiency of a solar cell is the addition of a back-surface field (BSF) region, in order to reduce the recombination of minority carriers at the rear of the cell. This can give rise to an increase of the short circuit current density and the open circuit voltage of the cell. Conventionally, p⁺ aluminum-diffused or boron-diffused regions in p-type Ge substrates serve as the BSF region. Nevertheless, the short-circuit current density in multi-junction solar cells with a thick Ge substrate is primarily limited by the sub cells that are above the Ge cell. On the other hand, an increase in the open-circuit voltage is limited to tens of millivolts using conventionally diffused BSF regions, due to the relatively small energy band-offset between the BSF region and the Ge substrate. Therefore, the resulting increase in the open-circuit voltage for the Ge bottom cell will not be significantly high to justify an additional processing step for the diffusion of Al or boron. As a result, the current multi-junction technology does not employ a BSF region to the Ge bottom cell, due to the use of a relatively thick Ge substrate.

### SUMMARY

The present disclosure includes the introduction of a back-surface field structure to a germanium bottom cell of a multi-junction photovoltaic device which can lead to significant enhancement of the total open-circuit voltage of the photovoltaic device. The back-surface field structure of the present disclosure includes at least one intrinsic hydrogenated silicon-containing layer, which may optionally include Ge, C or both Ge and C, in contact with a surface of the germanium-containing layer, and at least one doped hydrogenated silicon-containing layer, which also may optionally include one of Ge and C, in contact with a surface of the at least one intrinsic hydrogenated silicon-containing layer. The intrinsic and/or doped hydrogenated silicon-containing layers can be multilayers with different Ge and C contents. The intrinsic and/or doped hydrogenated silicon-containing layers can be amorphous, nano/micro-crystalline, poly-crystalline or single-crystalline.

In one embodiment, a multi-junction III-V photovoltaic device is provided that includes at least one top cell comprised of at least one III-V compound semiconductor material. The device further includes a bottom cell that is in contact with a surface of the at least one top cell. The bottom cell includes a germanium-containing layer in contact with the surface of the at least one top cell, at least one intrinsic hydrogenated silicon-containing layer in contact with a surface of the germanium-containing layer, and at least one doped hydrogenated silicon-containing layer in contact with a surface of the at least one intrinsic hydrogenated silicon-containing layer. The intrinsic and/or doped hydrogenated silicon-containing layers can be amorphous, nano/micro-crystalline, poly-crystalline or single-crystalline.

In another embodiment, a method of forming a multi-junction III-V photovoltaic device is provided. The method includes forming at least one intrinsic hydrogenated silicon-containing layer in contact with a surface of a germanium-containing layer. Next, at least one doped hydrogenated silicon-containing layer is formed in contact with a surface of the at least one intrinsic hydrogenated silicon-containing layer. The intrinsic and/or doped hydrogenated silicon-containing layers can be amorphous, nano/micro-crystalline, poly-crystalline or single-crystalline.

### BRIEF DESCRIPTION OF THE DRAWINGS

FIG. 1 is a pictorial representation (through a cross sectional view) depicting a photovoltaic device in accordance with one embodiment of the present disclosure.

FIG. 2 is a pictorial representation (through a cross sectional view) depicting a photovoltaic device in accordance with another embodiment of the present disclosure.

FIG. 3 is a pictorial representation (through a cross sectional view) illustrating the formation of at least one intrinsic hydrogenated silicon-containing layer on a surface of a germanium-containing layer in accordance with an embodiment of the present disclosure.

FIG. 4 is a pictorial representation (through a cross sectional view) illustrating the structure of FIG. 3 after formation of at least one doped hydrogenated silicon-containing layer on a surface of the at least one intrinsic hydrogenated silicon-containing layer in accordance with an embodiment of the present disclosure.

FIG. 5 is a pictorial representation (through a cross sectional view) illustrating the structure of FIG. 4 after formation of a conductive contact on a surface of the at least one doped hydrogenated silicon-containing layer in accordance with an embodiment of the present disclosure.

### DETAILED DESCRIPTION

The present disclosure, which provides photovoltaic devices with enhanced total open-circuit voltage, will now be described in greater detail by referring to the following discussion and drawings that accompany the present application. It is noted that the drawings of the present application are provided for illustrative purposes only and, as such, the drawings are not drawn to scale. It is also noted that in the drawings like and corresponding elements are referred to using like reference numerals.

In the following description, numerous specific details are set forth, such as particular structures, components, materials, dimensions, processing steps and techniques, in order to provide an understanding of the various embodiments of the present disclosure. However, it will be appreciated by one of ordinary skill in the art that the various embodiments of the present disclosure may be practiced without these specific details. In other instances, well-known structures or processing steps have not been described in detail in order to avoid obscuring the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present disclosure provides a back-surface field structure to a germanium bottom cell of a multi-junction photovoltaic device which can lead to significant enhancement of the total open-circuit voltage of the multi-junction photovoltaic device. By “total open circuit voltage” it is meant a voltage from 1.2 V to 2.7 V. By “significant enhancement” it is meant an improvement of 50 mV to 500 mV.

As used herein, a “photovoltaic device” is a device such as a solar cell that produces free electrons and/or vacancies, i.e., holes, when exposed to radiation, such as light, and results in the production of an electric current. A photovoltaic device typically includes layers of p-type conductivity and n-type conductivity that share an interface to provide a junction.

In the present disclosure, a back-surface field structure denotes a structure that includes a doped region having a higher dopant concentration than a germanium-containing layer and/or a lower electron affinity (χₑ) than the germanium-containing layer (in case of n-type doping), and/or a larger sum of electron affinity and bandgap (E_{g}), i.e. χₑ+E_{g} than the germanium-containing layer (in case of p-type doping). The back-surface field structure and the germanium-containing layer typically have the same conductivity type, e.g., p-type or n-type conductivity. The junction between the back-surface field structure and the germanium-containing layer creates an electric field which introduces a barrier to minority carrier flow to the rear surface. The back-surface field structure therefore reduces the rate of carrier recombination at the rear surface, and as such has a net effect of passivating the rear surface of the solar cell.

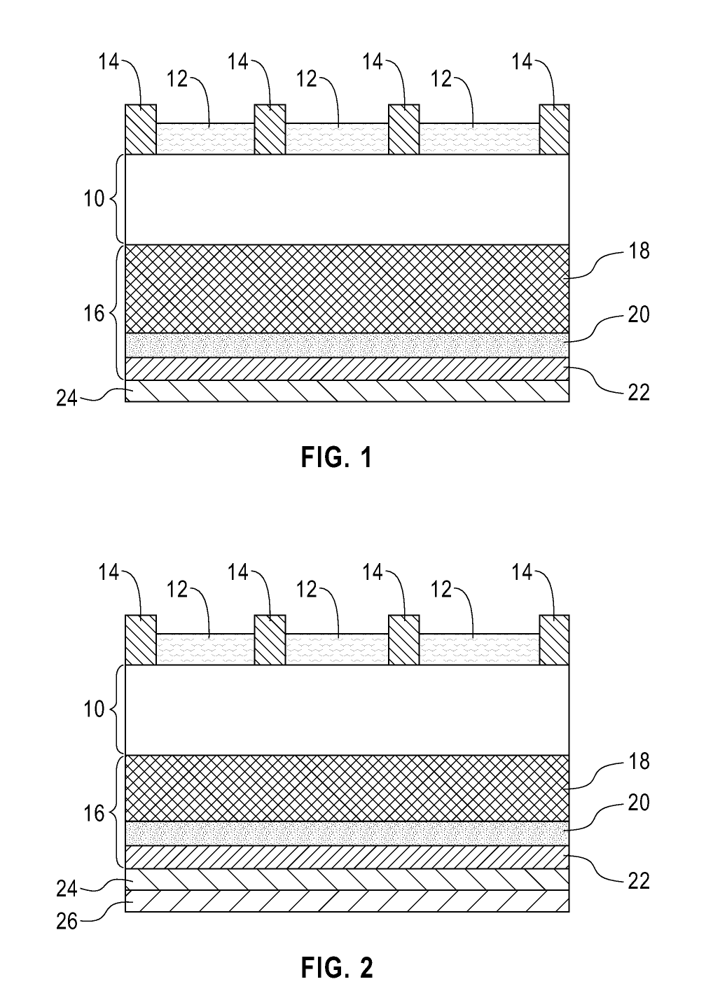

Reference is now made to FIGS. 1 and 2 which illustrate photovoltaic devices in accordance with various embodiments of the present disclosure. Each photovoltaic device of the present disclosure includes at least one top cell 10. The at least one top cell 10 of the present disclosure is comprised of at least one III-V semiconductor material. The at least one at least III-V semiconductor material includes at least one element from Group III of the Periodic Table of Elements and at least one element from Group V of the Periodic Table of Elements. The III-V semiconductor material that can be employed may comprise a binary, i.e., two element, III-V semiconductor material, a ternary, i.e., three element, III-V semiconductor material, or a quaternary, i.e., four element, III-V semiconductor material. III-V semiconductor materials including greater than 4 elements can also be used within the top cell 10 of the present disclosure.

Illustrative examples of III-V semiconductor materials that can be present within the at least one top cell 10 include, but are not limited to, aluminum antimonide (AlSb), aluminum arsenide (AlAs), aluminum nitride (AlN), aluminum phosphide (AlP), gallium arsenide (GaAs), gallium phosphide (GaP), indium antimonide (InSb), indium arsenic (InAs), indium nitride (InN), indium phosphide (InP), aluminum gallium arsenide (AlGaAs), indium gallium phosphide (InGaP), aluminum indium arsenic (AlInAs), aluminum indium antimonide (AlInSb), gallium arsenide nitride (GaAsN), gallium arsenide antimonide (GaAsSb), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), indium arsenide antimonide phosphide (InArSbP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide aluminum antimonide (GaInNAsSb), gallium indium arsenide antimonide phosphide (GaInAsSbP), and combinations thereof.

Each photovoltaic device also includes a bottom cell 16 in contact with a surface of the at least one top cell 10. In accordance with the present disclosure, the bottom cell 16 includes a germanium-containing layer 18 in contact with a surface of the at least one top cell 10, at least one intrinsic hydrogenated silicon-containing layer 20 that is in contact with a surface of the germanium-containing layer 18, and at least one doped hydrogenated silicon-containing layer 22 that is in contact with a surface of the at least one intrinsic hydrogenated silicon-containing layer 20. The intrinsic and/or doped hydrogenated silicon-containing layers (20 and 22) can be amorphous, nano/micro-crystalline, poly-crystalline or single-crystalline.

The term “single crystalline” denotes a crystalline solid in which the crystal lattice of the entire material is substantially continuous and substantially unbroken to the edges of the material, with substantially no grain boundaries. The term “nano/micro-crystalline” denotes a material having small grain crystallites embedded within an amorphous phase. The term “poly-crystalline” denotes a material solely containing crystalline grains separated by grain boundaries. The term “amorphous” denotes that the semiconductor layer lacks a well defined crystal structure.

The germanium-containing layer 18 includes a material that contains at least germanium therein. In one embodiment, the germanium-containing layer 18 of the bottom cell 16 contains germanium in a content that is greater than 50 atomic %. In another embodiment, the germanium-containing layer 18 contains germanium in a content that is greater than 99 atomic %. In yet another embodiment, the germanium-containing layer 18 is a pure germanium layer, i.e., a germanium-containing material having 100 atomic % germanium.

In one embodiment of the present disclosure, the germanium-containing layer 18 can be single crystalline.

The germanium-containing layer 18 that can be employed in the present disclosure may be undoped (i.e., intrinsic) or doped. When doped, the germanium-containing layer 18 may have an n-type or p-type conductivity. As used herein, “p-type” refers to the addition of impurities to an intrinsic semiconductor that creates deficiencies of valence electrons (i.e., holes). As used herein, “n-type” refers to the addition of impurities that contributes free electrons to an intrinsic semiconductor. The term “conductivity type” denotes a p-type or n-type dopant. Examples of p-type dopants that can be used to provide a p-type conductivity to the germanium-containing layer 18 include, but are not limited to, gallium (Ga), boron (B), and aluminum (Al). Examples of n-type dopants that can be used to provide an n-type conductivity to the germanium-containing layer 18 include, but are not limited to, antimony (Sb), arsenic (As), and phosphorous (P).

The dopant that provides the conductivity type of the germanium-containing layer 18 may be introduced by an in-situ doping process. By “in-situ” it is meant that the dopant that provides the conductivity type of the material layer is introduced as the material layer is being formed. The p-type and/or n-type dopant for the germanium-containing layer 18 may also be introduced following the deposition of the germanium-containing layer 18 using at least one of plasma doping, ion implantation, and/or outdiffusion from a disposable diffusion source (e.g., borosilicate glass).

When doped to a p-type conductivity, the concentration of the p-type dopant in the germanium-containing layer 18 can range from 10¹⁴ atoms/cm³ to 10¹⁸ atoms/cm³. When doped to an n-type conductivity, the concentration of the n-type dopant in the germanium-containing layer 18 can range from 10¹⁴ atoms/cm³ to 10¹⁸ atoms/cm³.

The thickness of the germanium-containing layer 18 of the bottom cell 16 of the present disclosure may vary. In one embodiment, the thickness of the germanium-containing layer 18 of the bottom cell 16 of the present disclosure is from 0.5 μm to 150 μm. In another embodiment, the thickness of the germanium-containing layer 18 of the bottom cell 16 of the present disclosure is 20 μm or less. It is noted that the above thicknesses for the germanium-containing layer 18 have been provided for illustrative purposes only, and are not intended to limit the present disclosure.

As stated above, the bottom cell 16 of the present disclosure also includes at least one intrinsic hydrogenated silicon-containing layer 20. The at least one intrinsic hydrogenated silicon-containing layer 20 can be amorphous, nano/micro-crystalline, poly-crystalline or single-crystalline. The term “at least one” denotes that one or more layers (i.e., 2, 3, 4, 5, etc.) are employed. Typically, from 1 to 3 layers of intrinsic hydrogenated amorphous, nano/micro-crystalline, poly-crystalline or single-crystalline silicon-containing materials are employed. When more that one layer is employed, the other layers may have the same or different composition. The term “hydrogenated” denotes that the semiconductor layer includes hydrogen therein. The term “intrinsic” denotes that the semiconductor material is undoped, i.e., a substantially pure semiconductor material without any significant dopant present therein. The number of charge carriers in the intrinsic semiconductor is determined by the properties of the material itself instead of the amount of impurities, i.e., dopants. Typically, in intrinsic semiconductors the number of excited electrons and the number of holes are equal (n=p). The at least one intrinsic hydrogenated silicon-containing layer 20 can serve to passivate the top surface of the germanium-containing layer 18, and reduce electron-hole recombination.

In one embodiment, the at least one intrinsic hydrogenated silicon-containing layer 20 comprises a silicon semiconductor material that contains silicon in a content of 50 atomic % or greater. In another embodiment, the at least one intrinsic hydrogenated silicon-containing layer 20 contains silicon in a content that is greater than 95 atomic %. In yet another embodiment, the at least one intrinsic hydrogenated silicon-containing layer 20 is a pure silicon layer, i.e., a silicon-containing material having 100 atomic % silicon.

In one embodiment, the at least one intrinsic hydrogenated silicon-containing layer 20 may include germanium therein. In another embodiment, the at least one intrinsic hydrogenated silicon-containing layer 20 may also include carbon present therein. In yet another embodiment of the present disclosure, the at least one intrinsic hydrogenated silicon-containing layer 20 may also include both germanium and carbon present therein.

In one embodiment, the least one intrinsic hydrogenated silicon-containing layer 20 can be an intrinsic hydrogenated amorphous, nano/micro-crystalline, poly-crystalline or single-crystalline silicon layer, an intrinsic hydrogenated amorphous, nano/micro-crystalline, poly-crystalline or single-crystalline silicon-germanium layer, an intrinsic hydrogenated amorphous, nano/micro-crystalline, poly-crystalline or single-crystalline silicon-carbon layer, an intrinsic hydrogenated amorphous, nano/micro-crystalline, poly-crystalline or single-crystalline silicon-germanium-carbon layer, or multilayers thereof.

In embodiments in which the at least one intrinsic hydrogenated silicon-containing layer 20 includes germanium, the content of germanium within the at least one intrinsic hydrogenated silicon-containing layer 20 is typically from greater than 0 atomic % to less than 100 atomic %, with a range from greater than 0 atomic % to 50 atomic %, being more typical.

In embodiments in which the at least one intrinsic hydrogenated silicon-containing layer 20 includes carbon, the content of carbon within the at least one intrinsic hydrogenated silicon-containing layer 20 is typically from greater than 0 atomic % to 80 atomic %, with a range from greater than 0 atomic % to 50 atomic %, being more typical.

In embodiments in which the at least one intrinsic hydrogenated silicon-containing layer 20 includes germanium and carbon, the content of germanium within the at least one intrinsic hydrogenated silicon-containing layer 20 is typically from greater than 0 atomic % to less than 100 atomic % and the content of carbon within that at least one intrinsic hydrogenated silicon-containing layer 20 is typically within a range from greater than 0 atomic % to 80 atomic %. In another embodiment, and when both germanium and carbon are present in the at least one intrinsic hydrogenated silicon-containing layer 20, the content of germanium within the at least one intrinsic hydrogenated silicon-containing layer 20 is typically from greater than 0 atomic % to 50 atomic % and the content of carbon within that at least one intrinsic hydrogenated silicon-containing layer 20 is typically within a range from greater than 0 atomic % to 50 atomic %.

In accordance with the present disclosure, the content of carbon and/or germanium within the at least one intrinsic hydrogenated silicon-containing layer 20 may be constant or vary across the layer. In some embodiments, the at least one intrinsic hydrogenated silicon-containing layer 20 may also contain at least one of nitrogen, oxygen, fluorine, and deuterium.

In one embodiment, the thickness of the at least one intrinsic hydrogenated silicon-containing layer 20 is from 1 nm to 20 nm. In another embodiment, the thickness of the at least one intrinsic hydrogenated silicon-containing layer 20 is from 2 nm to 10 nm. Other thickness that are lesser and greater than that recited above can also be employed.

As stated above, the bottom cell 16 of the present disclosure also includes at least one doped hydrogenated silicon-containing layer 22. The at least one doped hydrogenated silicon containing layer 22 can be amorphous, nano/micro-crystalline, poly-crystalline or single-crystalline. The term “at least one” denotes that one or more layers (i.e., 2, 3, 4, 5, etc.) are employed. Typically, from 1 to 5 layers of doped hydrogenated silicon-containing materials are employed. When more that one layer is employed, the other layers may have the same or different composition and/or dopant type and concentration. The term “hydrogenated” denotes that the semiconductor layer includes hydrogen therein. The terms “amorphous” “nano/micro-crystalline”, “poly-crystalline” and “single-crystalline” have the same meaning as denoted above.

In one embodiment, the at least one doped hydrogenated silicon-containing layer 22 comprises a silicon semiconductor material containing silicon in a content of 50 atomic % or greater. In another embodiment, the at least one doped hydrogenated silicon-containing layer 22 contains silicon in a content that is greater than 95 atomic %. In yet another embodiment, the at least one doped hydrogenated silicon-containing layer 22 is a pure silicon layer, i.e., a silicon-containing material having 100 atomic % silicon.

In one embodiment, the at least one doped hydrogenated silicon-containing layer 22 may include germanium therein. In another embodiment, the at least one doped hydrogenated silicon-containing layer 22 may also include carbon present therein. In yet another embodiment of the present disclosure, the at least one doped hydrogenated silicon-containing layer 22 may also include both germanium and carbon present therein.

In one embodiment, the least one doped hydrogenated silicon-containing layer 22 can be a doped hydrogenated amorphous, nano/micro-crystalline, poly-crystalline or single-crystalline silicon layer, a doped hydrogenated amorphous, nano/micro-crystalline, poly-crystalline or single-crystalline silicon-germanium layer, a doped intrinsic hydrogenated amorphous, nano/micro-crystalline, poly-crystalline or single-crystalline silicon-carbon layer, a doped intrinsic hydrogenated amorphous, nano/micro-crystalline, poly-crystalline or single-crystalline silicon-germanium-carbon layer, or multilayers thereof.

In embodiments in which the at least one doped hydrogenated silicon-containing layer 22 includes germanium, the content of germanium within the at least one doped hydrogenated silicon-containing layer 22 is typically from greater than 0 atomic % to less than 100 atomic %, with a range from greater than 0 atomic % to 50 atomic %, being more typical.

In embodiments in which the at least one doped hydrogenated silicon-containing layer 22 includes carbon, the content of carbon within the at least one doped hydrogenated silicon-containing layer 22 is typically from greater than 0 atomic % to 80 atomic %, with a range from greater than 0 atomic % to 50 atomic %, being more typical.

In embodiments in which the at least one doped hydrogenated silicon-containing layer 22 includes germanium and carbon, the content of germanium within the at least one doped hydrogenated silicon-containing layer 22 is typically from greater than 0 atomic % to less than 100 atomic % and the content of carbon within that at least one doped hydrogenated silicon-containing layer 22 is typically within a range from greater than 0 atomic % to 80 atomic %. In another embodiment, and when both germanium and carbon are present in the at least one doped hydrogenated silicon-containing layer 22, the content of germanium within the at least one doped hydrogenated silicon-containing layer 22 is typically from greater than 0 atomic % to 50 atomic % and the content of carbon within that at least one doped hydrogenated silicon-containing layer 22 is typically within a range from greater than 0 atomic % to 50 atomic %.

In accordance with the present disclosure, the content of carbon and/or germanium within the at least one doped hydrogenated silicon-containing layer 22 may be constant or vary across the layer. In some embodiments, the at least one doped hydrogenated silicon-containing layer 22 may also contain at least one of nitrogen, oxygen, fluorine, and deuterium.

The at least one doped hydrogenated silicon-containing layer 22 has an n-type or p-type conductivity. Typically, the at least one doped hydrogenated silicon-containing layer 22 has the same conductivity as the germanium-containing layer 18. Thus, when the germanium-containing layer 18 has a p-type conductivity, the at least one doped hydrogenated silicon-containing layer 22 also has a p-type conductivity. When the germanium-containing layer 18 has an n-type conductivity, the at least one doped hydrogenated silicon-containing layer 22 also has an n-type conductivity. The term “p-type” refers to the addition of impurities to an intrinsic semiconductor that creates deficiencies of valence electrons (i.e., holes). As used herein, “n-type” refers to the addition of impurities that contributes free electrons to an intrinsic semiconductor. The term “conductivity type” denotes a p-type or n-type dopant. Examples of p-type dopants that can be used to provide a p-type conductivity to the at least one doped hydrogenated silicon-containing layer 22 include elements from Group IIIA of the Periodic Table of Elements. Examples of n-type dopants that can be used to provide an n-type conductivity to the at least one doped hydrogenated silicon-containing layer 22 include elements from Group VA of the Periodic Table of Elements.

The dopant that provides the conductivity type of the at least one doped hydrogenated silicon-containing layer 22 may be introduced by an in-situ doping process. By “in-situ” it is meant that the dopant that provides the conductivity type of the material layer is introduced as the material layer is being formed. The p-type and/or n-type dopant for the at least one at least one doped hydrogenated silicon-containing layer 22 may also be introduced following the deposition of the using at least one of plasma doping, ion implantation, and/or outdiffusion from a disposable diffusion source (e.g., borosilicate glass).

When doped to a p-type conductivity, the concentration of the p-type dopant in the at least one doped hydrogenated silicon-containing layer 22 can range from 10¹⁴ atoms/cm³ to 10²⁰ atoms/cm³. When doped to an n-type conductivity, the concentration of the n-type dopant in the at least one doped hydrogenated silicon-containing layer 22 can range from 10¹⁴ atoms/cm³ to 10²⁰ atoms/cm³.

In one embodiment, the thickness of the at least one doped hydrogenated silicon-containing layer 22 is from 2 nm to 50 nm. In another embodiment, the thickness of the at least one doped hydrogenated silicon-containing layer 22 is from 2 nm to 30 nm. Other thickness that are lesser and greater than that recited above can also be employed.

Each photovoltaic device of the present disclosure may also include a metal grid that is located on an upper most surface of the at least one top cell 10. The metal grid includes a plurality of metal fingers 14 which are located within a plurality of patterned antireflective coatings 12. The metal fingers 14 may comprise a metal or metal alloy. In one embodiment, the metal fingers 14 are comprised of Al. In another embodiment, the metal fingers 14 can be comprised of one of Ni, Co, Pt, Pd, Fe, Mo, Ru, W, Pd, Zn, Sn, Au, AuGe and Ag. Each metal finger 14 may have the same or different thickness. Typically, the thickness of each of the metal fingers 14 is from 5 nm to 15 μm, with a thickness from 1 μm to 10 μm being more typical.

The patterned antireflective coatings 12 that can be employed in the present disclosure include any conventional ARC material such as, for example, an inorganic ARC or an organic ARC. In one embodiment of the present disclosure, the ARC material comprises silicon nitride, silicon oxide, silicon oxynitride, magnesium fluoride, zinc sulfide, titanium oxide, aluminum oxide or a combination of thereof. Typically, the thickness of each of the patterned antireflective coatings 12 is from 10 nm to 200 nm.

Each photovoltaic device may also include a conductive contact 24 that is located on the bottom most surface of the bottom cell 16. The conductive contact 24 that is present includes at least one transparent conductive material. Throughout this disclosure, an element is “transparent” if the element is sufficiently transparent in the visible electromagnetic spectral range. The conductive contact 24 includes a conductive material that is transparent in the range of electromagnetic radiation at which photogeneration of electrons and holes occur within the photovoltaic device. In one embodiment, the transparent conductive material can include a transparent conductive oxide such as, but not limited to, a fluorine-doped tin oxide (SnO₂:F), an aluminum-doped zinc oxide (ZnO:Al), tin oxide (SnO) and indium tin oxide (InSnO₂, or ITO for short). The thickness of the conductive contact 24 may vary depending on the type of transparent conductive material employed, as well as the technique that was used in forming the transparent conductive material. Typically, and in one embodiment, the thickness of the conductive contact 24 ranges from 20 nm to 500 nm. Other thicknesses, including those less than 20 nm and/or greater than 500 nm can also be employed.

In some embodiments, and as shown in FIG. 2, the photovoltaic device may also include a handle substrate 26 that is located beneath the conductive contact 24. This embodiment is typically employed, in instances in which the germanium-containing layer 18 has a thickness of 20 μm or less. Examples of handle substrates that can be employed in the present disclosure include, but are not limited to, silicon substrates, glass, Telfon, Invar, polyimide and Kapton sheets. The thickness of the handle substrate 26 is typically from 50 μm to 10 mm, with a thickness from 50 μm to 2 mm being more typical.

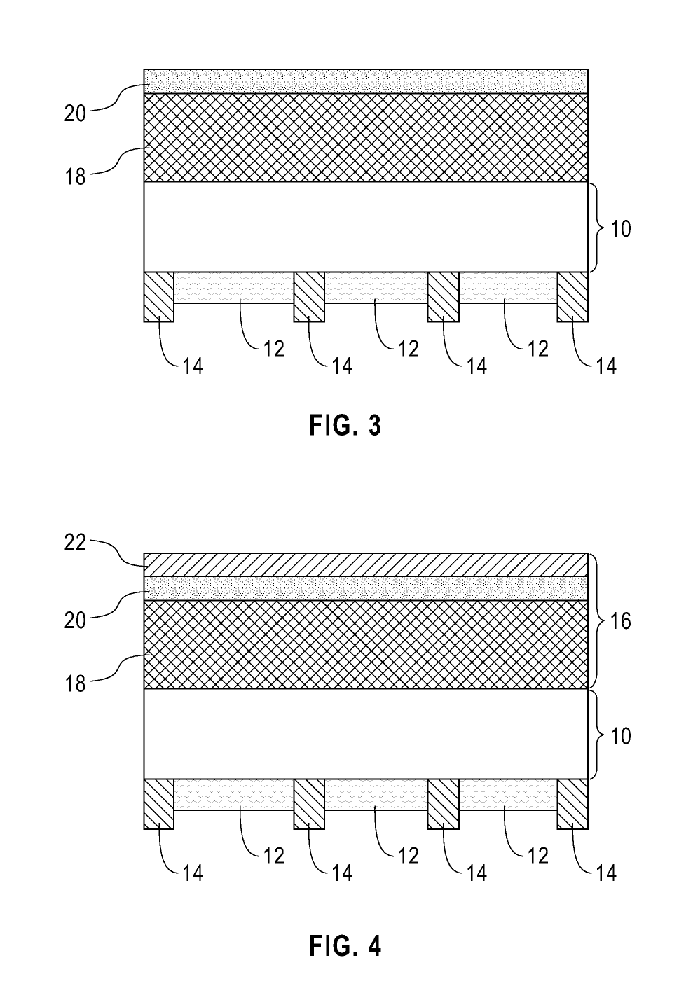

Reference is now made to FIGS. 3-5 which illustrate basic processing steps that can be used in forming some of the photovoltaic devices of the present disclosure. In particular, FIGS. 3-5 illustrate an embodiment in which the photovoltaic device of FIG. 1 is made. The photovoltaic device shown in FIG. 2 would be made in a similar manner expect that the thickness of the germanium-containing layer 18 would be from 20 μm or less and a handle substrate 26 would be formed on the bottom most surface of the bottom cell 16. The handle substrate 26 can be formed utilizing a conventional deposition process. Alternatively, a layer transfer process could be used in forming the handle substrate 26 to the structure.

The method of the present disclosure includes forming at least one intrinsic hydrogenated silicon-containing layer 20 in contact with a surface of a germanium-containing layer 18. Next, at least one doped hydrogenated silicon-containing layer 22 is formed in contact with a surface of the at least one intrinsic hydrogenated silicon-containing layer 20. The other components of the photovoltaic device shown in FIGS. 1 and 2 may be formed prior to and/or after any of the steps mentioned above.

For example, and as is shown in FIG. 3, the method begins by forming at least one intrinsic hydrogenated silicon-containing layer 20 on a surface of a germanium-containing layer 18 which was previously processed to include the at least one top cell 10, metal fingers 14 and patterned antireflective coating 12. Layer 20 can be amorphous, nano/micro-crystalline, poly-crystalline or single-crystalline. Although the drawings and description that follow illustrate the presence of the at least one top cell 10, metal fingers 14 and patterned antireflective coatings 12, these elements can be formed either prior to or after formation of the at least one intrinsic hydrogenated silicon-containing layer 20.

In accordance with one embodiment of the present disclosure, a germanium-containing layer 18 is first provided. The germanium-containing layer 18 can be formed utilizing techniques well known to those skilled in the art including, for example, deposition and growth. In one embodiment, the germanium-containing layer 18 can be formed utilizing a Czochralsky (CZ) method. The Czochralsky (CZ) method includes taking a seed of single-crystal germanium and placing it in contact with the top surface of molten germanium. As the seed is slowly raised (or pulled), atoms of the molten germanium solidify in the pattern of the seed and extend the single-crystal structure. The single-crystal structure is then sawn into wafers, i.e., substrates that can provide the germanium-containing layer 18.

After providing the germanium-containing layer 18, the top cell including the III-V semiconductor material can be formed on one surface of the germanium-containing layer 18 utilizing a conventional deposition processes. Alternatively, the at least one top cell 10, with or without the metal fingers 14 and patterned antireflective coating 12, can be provided to one surface of the germanium-containing layer 18 by a layer transfer process. The metal grid that is present on the at least one top cell 10 can be formed by first providing a blanket layer of an antireflective coating on a surface of the at least one top cell 10 that is opposite the surface of the at least one top cell 10 that is direct contact with the germanium-containing layer 18. The blanket layer of antireflective coating can be formed utilizing any conventional deposition process. Following deposition of the blanket layer of antireflective coating, the blanket layer of antireflective coating is patterned by conventional techniques, such as lithography and etching.

The patterning removes portions of the blanket layer of antireflective coating, while leaving other portions of the blanket layer of antireflective coating on the surface of the at least one top cell 10. Metal fingers 14 are then formed. In one embodiment, the metal fingers 14 are formed by screen printing utilizing a conductive paste. Alternatively, the metal fingers 14 can be formed by sputtering, thermal or ebeam evaporation, or plating.

The at least one intrinsic hydrogenated silicon-containing layer 20 that is formed on a surface of a germanium-containing layer 18 is formed by any physical or chemical growth deposition process. For example, plasma enhanced chemical vapor deposition can be used to form the at least one intrinsic hydrogenated silicon-containing layer 20. In one embodiment, the at least one intrinsic hydrogenated silicon-containing layer 20 is formed in a process chamber including at least one semiconductor precursor source material gas and a carrier, which may contain hydrogen. In one embodiment, the at least one semiconductor precursor source material gas includes a silicon-containing precursor gas. An optional carbon-containing source gas and/or germanium-containing precursor source gas may also be used. Examples of silicon-containing precursor source gases that can be employed in forming the at least one intrinsic hydrogenated silicon-containing layer 20 include, but are not limited to, SiH₄ Si₂H₆, SiH₂Cl₂ and SiCl₄. Examples of carbon-containing precursor source gases that can be employed in forming the at least one intrinsic hydrogenated silicon-containing layer 20 include, but are not limited to, CCl₄, and CH₄. Examples of germanium-containing precursor source gases that can be employed in forming the at least one intrinsic hydrogenated silicon-containing layer 20 include, but are not limited to, GeH₄.

Referring now to FIG. 4, there is illustrated the structure of FIG. 3 after formation of the at least one doped hydrogenated silicon-containing layer 22 on a surface of the at least one intrinsic hydrogenated silicon-containing layer 20 in accordance with an embodiment of the present disclosure. Layer 22 can be amorphous, nano/micro-crystalline, poly-crystalline or single-crystalline. Layers 20 and 22 can have the same or different crystal structure. The at least one doped hydrogenated silicon-containing layer 22 can be formed by any physical or chemical growth deposition process. For example, plasma enhanced chemical vapor deposition can be used to form the at least one doped hydrogenated silicon-containing layer 22. The dopants can be incorporated during the deposition process by including at least one dopant atom therein. This process is referred to as an in-situ deposition process. Alternatively, and as mentioned above, the dopants can be incorporated into a previously undoped hydrogenated silicon-containing layer.

In one embodiment, the at least one doped hydrogenated silicon-containing layer 22 is formed in a process chamber including at least at least one semiconductor precursor source material gas and a carrier, which may contain hydrogen. In one embodiment, the at least one semiconductor precursor source material gas includes a silicon-containing precursor gas. An optional carbon-containing source gas and/or germanium-containing precursor source gas may also be used. Examples of silicon-containing precursor source gases that can be employed in forming layer 22 include, but are not limited to, SiH₄ Si₂H₆, SiH₂Cl₂ and SiCl₄. Examples of carbon-containing precursor source gases that can be employed in forming layer 22 include, but are not limited to, CCl₄, and CH₄. Examples of germanium-containing precursor source gases that can be employed in forming layer 22 include, but are not limited to, GeH₄.

In embodiments in which the dopant is introduced into the at least one doped hydrogenated silicon-containing layer 22, a dopant source can be present during the deposition process. Alternatively, the dopants can be introduced after deposition of layer 22, as described above.

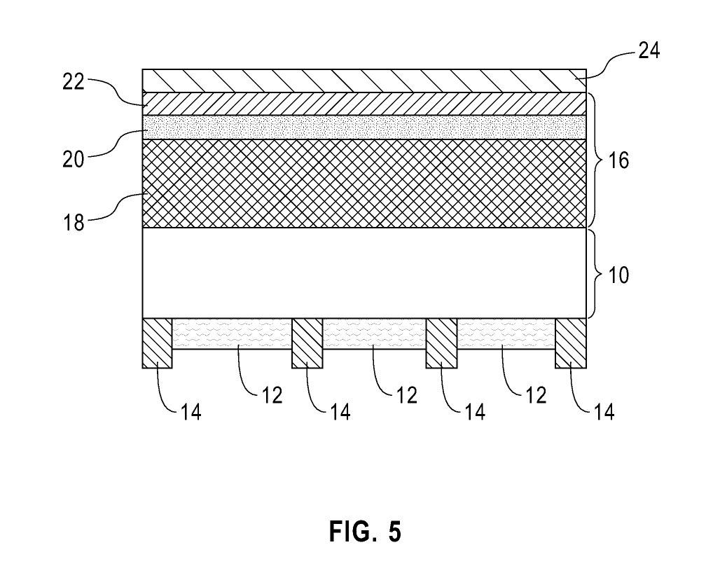

Referring to FIG. 5, there is illustrated the structure of FIG. 4 after formation of a conductive contact 24 on a surface of the at least one doped hydrogenated silicon-containing layer 22 in accordance with an embodiment of the present disclosure. The at least one conductive contact 24 can be formed utilizing a deposition process such as, for example, sputtering or chemical vapor deposition. Examples of chemical vapor deposition process suitable for use in the present disclosure include, but are not limited to, APCVD, LPCVD, PECVD, MOCVD and combinations thereof. Examples of sputtering processes that can be used include, for example, RF and DC magnetron sputtering.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method of fabricating a multi-junction III-V photovoltaic device comprising:
forming at least one intrinsic hydrogenated silicon-containing layer in contact with a surface of a germanium-containing layer; and
forming at least one doped hydrogenated silicon-containing layer in contact with a surface of the at least one intrinsic hydrogenated silicon-containing layer.

2. The method of claim 1, wherein said at least one intrinsic hydrogenated silicon-containing layer further includes one of germanium and carbon.

3. The method of claim 1, wherein said at least one doped hydrogenated silicon-containing layer further includes at least one of carbon and germanium.

4. The method of claim 1, wherein said germanium-containing layer has a p-type conductivity formed therein prior to forming that least one intrinsic hydrogenated silicon-containing layer thereon.

5. The method of claim 1, further comprising forming a top cell comprised of at least one III-V compound semiconductor material on another surface of the germanium-containing layer.

6. The method of claim 5, further comprising forming a plurality of metal fingers located within a plurality of patterned antireflective coatings, said plurality of metal fingers and said plurality of patterned antireflective coatings are present on another surface of the top cell.

7. The method of claim 1, further comprising forming a transparent conductive material layer located on another surface of said at least one doped hydrogenated silicon-containing layer.

8. The method of claim 1, wherein said germanium-containing layer has a thickness of 20 μm or less, and wherein a transparent conductive material layer and a handle substrate are formed on another surface of the at least one doped hydrogenated silicon-containing layer.
